(19) United States
(12) Patent Application Publication
(10) Pub. No.: US 2025/0366348 A1
(43) Pub. Date: Nov. 27, 2025

(54) DISPLAY DEVICE INCLUDING A RESIN LAYER AND DAMS, METHOD OF MANUFACTURING THE DISPLAY DEVICE, AND ELECTRONIC DEVICE INCLUDING THE DISPLAY DEVICE

(71) Applicant: SAMSUNG DISPLAY CO., LTD., YONGIN-SI (KR)

(72) Inventors: JEONGWEON SEO, Yongin-si (KR); TAEWOO PARK, Yongin-si (KR); GWANGTAEK LEE, Yongin-si (KR); JEONGHO HWANG, Yongin-si (KR)

(21) Appl. No.: 19/013,639

(22) Filed: Jan. 8, 2025

(30) Foreign Application Priority Data
May 27, 2024 (KR) 10-2024-0068864

(51) Int. Cl. H10K 59/80; H10K 59/12

(52) U.S. Cl. CPC H10K 59/873; H10K 59/1201

(57) ABSTRACT

A display device includes a base layer including a first area and a second area proximate to the first area. A first dam is disposed in the second area on the base layer. A second dam is disposed in the second area on the base layer and is spaced apart from the first dam. The first and second dams include a same material as one another. A resin layer is disposed on the base layer. The resin layer includes the same material as the first dam and the second dam. and the resin layer covers upper surfaces of each of the first dam and the second dam.

### CROSS-REFERENCE TO RELATED APPLICATION

This application claims priority under 35 U.S.C. § 119 to Korean Patent Application No. 10-2024-0068864, filed on May 27, 2024, the content of which is herein incorporated by reference in its entirety.

### TECHNICAL FIELD

The present disclosure relates to a display device and, more specifically, to a display device including a resin layer and dams and a method of manufacturing the display device, and an electronic device including the display device.

### DISCUSSION OF THE RELATED ART

In the manufacturing of a display device such as smartphones, televisions, smartwatches, and computer monitors, various layers are laminated onto a substrate. An adhesive resin layer is often used in this process. However, this resin tends to shrink during curing, which can result in incomplete coverage, especially at the edges of the display. To address this issue, dams are formed at the display's edges before applying the resin layer. These dams act as barriers, resisting the resin's shrinkage during curing and thereby preventing or reducing contraction. Ongoing research focuses on developing structures that minimize this resin layer contraction.

### SUMMARY

A display device includes a base layer including a first area and a second area proximate to the first area. A first dam is disposed in the second area on the base layer. A second dam is disposed in the second area on the base layer. The second dam is spaced apart from the first dam and includes a same material as the first dam. A resin layer is disposed on the base layer, including a same material as the first dam and the second dam, and covering upper surfaces of each of the first dam and the second dam.

The base layer may include a display panel including a light emitting diode that emits light.

The second dam may be disposed closer to the first area of the base layer than is the first dam.

The first dam may have a first height and the second dam may have a second height. The first height of the first dam may be different than the second height of the second dam.

The second height may be greater than the first height.

Each of the first height of the first dam and the second height of the second dam may be about 100 μm or less.

A planar shape of each of the first dam and the second dam may be a polygonal or circular shape.

An upper surface of the base layer on which the first dam and the second dam are disposed may be hydrophilic.

Each of the first dam and the second dam may include urethane resin, acrylic resin, and/or epoxy resin.

A planar area of the resin layer may be about 95% or more of a planar area of the base layer.

A width of the second area may be about 5 mm or less.

A method of manufacturing the display device includes performing a first surface treatment process on an upper surface of a second area of a base layer that includes a first area and the second area that is proximate to the first area. Dam resin is applied to the second area on the base layer. The dam resin is cured to form a first dam and a second dam that is spaced apart from the first dam. A main resin including a same material as the dam resin is applied to the first area and the second area of the base layer. The main resin is cured to form a resin layer covering upper surfaces of the first dam and the second dam.

The first surface treatment process may include performing a hydrophilic treatment process on the upper surface of the second area of the base layer.

In forming the first dam and the second dam, the second dam may be formed closer to the first area of the base layer than is the first dam.

The first dam may have a first height and the second dam may have a second height. The second height of the second dam may be different than the first height of the first dam.

The second height of the second dam may be greater than the first height of the first dam.

The method may further include performing a second surface treatment process on an upper surface of the first area of the base layer, prior to applying the main resin.

Performing the second surface treatment process may include performing a hydrophilic treatment process on the upper surface of the first area of the base layer.

Each of the first surface treatment process and the second surface treatment process may be a plasma treatment process.

In applying dam resin, the dam resin may be applied through an inkjet printing method.

An electronic device includes a display device and a processor configured to drive the display device, and wherein the display device includes a base layer including a first area and a second area proximate to the first area, a first dam disposed in the second area on the base layer, a second dam disposed in the second area on the base layer, the second dam being spaced apart from the first dam, and including a same material as the first dam, and a resin layer disposed on the base layer, including a same material as the first dam and the second dam, and covering upper surfaces of each of the first dam and the second dam.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a perspective view showing a display device according to an embodiment of the present disclosure.

FIG. 2 is a cross-sectional view showing a cross-section of the display device of FIG. 1.

FIG. 3 is a cross-sectional view showing a cross-section of the display panel of FIG. 2.

FIG. 4 is a plan view showing an embodiment of a base layer shown in FIG. 2.

FIG. 5 is an enlarged plan view of an embodiment of the AA of FIG. 4.

FIG. 6 is an enlarged plan view of an embodiment of AA of FIG. 4.

FIG. 7 is a cross-sectional view taken along line I-I′ of FIG. 5.

FIG. 8 is an enlarged plan view of an embodiment of AA of FIG. 4.

FIG. 9 is a cross-sectional view taken along line II-II′ of FIG. 8.

FIGS. 10, 11, 12, 13, 14, 15, 16, and 17 are views showing a method of manufacturing the dams and the resin layer of FIG. 9.

FIG. 18 is an enlarged plan view of an embodiment of AA area of FIG. 4.

FIG. 19 is a plan view showing an embodiment of the base layer included of FIG. 2.

FIG. 20 is an enlarged plan view of BB of FIG. 19.

FIG. 21 is a cross-sectional view of an embodiment taken along line V-V′ of FIG. 20.

FIG. 22 is a cross-sectional view of an embodiment taken along line V-V′ of FIG. 20.

FIG. 23 is a block-diagram showing an electronic device according to an embodiment of the present disclosure.

FIG. 24 is a schematic diagram of the electronic device according to various embodiments of FIG. 23.

### DETAILED DESCRIPTION

Regarding embodiments of the present disclosure disclosed in this text, specific structural and functional descriptions are provided for the purpose of explaining embodiments of the present disclosure, and the embodiments of the present disclosure may be implemented in various forms. The present disclosure, however, should not necessarily be construed as limited to the embodiments described in.

In this disclosure, various modifications may be made, various forms may be used, and specific embodiments will be illustrated in the drawings and described in detail in the text. However, this is not necessarily intended to limit the disclosure to a specific form disclosed, and it will be understood that all changes, equivalents, or substitutes which fall in the spirit and technical scope of the disclosure should be included.

Terms such as first, second, etc. may be used to describe various components, but the components should not necessarily be limited by the terms. The above terms may be used for a purpose of distinguishing one component from another component. For example, a first component may be referred to as a second component, and similarly, the second component may also be referred to as a first component without departing from the scope of the present disclosure.

When a component is referred to as being “connected” to another component, it should be understood that it may be directly connected or connected to the other component, but that other components may exist in between. Other expressions that describe the relationship between components, such as “between” and “immediately between” or “neighboring” and “directly adjacent to”, should be interpreted similarly.

As used herein, the singular forms “a,” “an” and “the” are intended to include the plural forms as well, unless the context clearly indicates otherwise. It will be further understood that the terms “include” and/or “including,” when used in this specification, specify the presence of stated features, integers, steps, operations, elements, and/or components, but do not preclude the presence or addition of one or more other features, integers, steps, operations, elements, components, and/or groups thereof.

Hereinafter, embodiments will be described in detail with reference to the accompanying drawings. The same reference numerals may be used for the same components in the drawings, and to the extent that an element is not described in detail with respect to this figure, it may be understood that the element is at least similar to a corresponding element that has been described elsewhere within the present disclosure.

In this specification, a plane may be defined by a first direction D1 and a second direction D2 that intersects the first direction D1. For example, the second direction D2 may be perpendicular to the first direction D1. In addition, a third direction D3 may be a normal direction of the plane. For example, the third direction D3 may be perpendicular to the plane formed by the first direction D1 and the second direction D2.

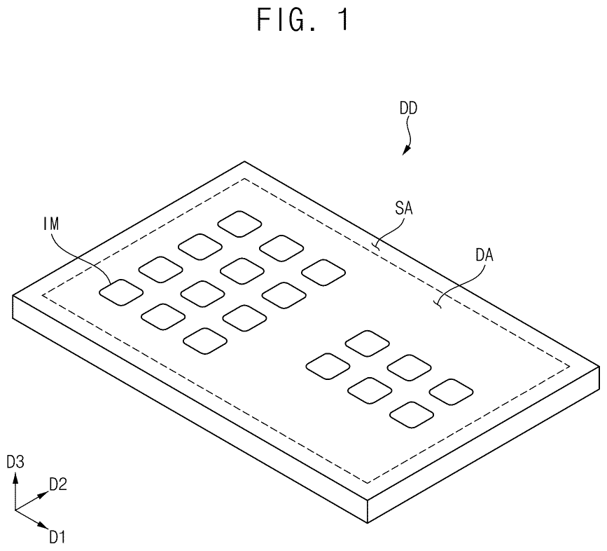

FIG. 1 is a perspective view showing a display device according to an embodiment of the present disclosure. The display device DD may be configured for use in a product such as a smartphone, a television, a smartwatch, or a computer monitor, although the display device DD may be configured for use in other sorts of products that include a display panel. When used in a smartphone, the display device DD may constitute a display panel that is either rigid or folding. The size and resolution of the display panel may be adapted for use in a smartphone, but may otherwise be substantially as described herein, complete with the various dams and resin layer described herein. When used in a television or computer monitor, the display device DD may constitute a display panel that is either planar (flat) or curved. The size and resolution of the display panel may be adapted for use in a television or computer monitor. When used in a smartwatch, the display device DD may constitute a display panel that is either rectangular or rounded and may have a size and resolution that may be adapted for use as a smartwatch. Other final products may also utilize the display device DD described herein such as a digital billboard, a vehicle navigation system or other vehicle display, a portable game console, a tablet computer, an e-book reader, a personal digital assistant (PDA), or an Internet-of-Things device such as a smart home appliance that includes a display panel.

Referring to FIG. 1, the display device DD may include a display area DA and a peripheral area SA. The display area DA may be surrounded by the peripheral area SA on at least two sides thereof. The display area DA is proximate to the peripheral area SA.

The display area DA may be an area capable of generating light or otherwise displaying an image by adjusting a transmittance of light provided from an external light source, such as a backlight. The peripheral area SA may be an area that does not display an image. However, embodiments of the present disclosure are not necessarily limited thereto, and at least a portion of the peripheral area SA may display an image.

The display area DA may display a plurality of images IM. Through the plurality of images IM, users may receive information from the display device DD.

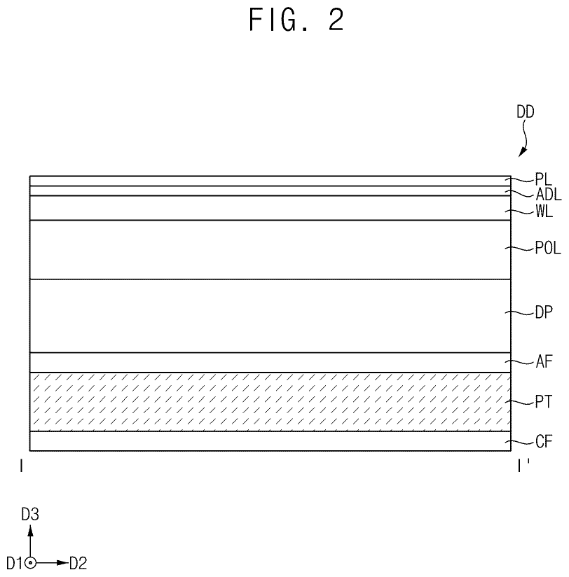

FIG. 2 is a cross-sectional view showing a cross-section of the display device of FIG. 1.

Referring to FIG. 2, the display device DD may include a cover film CF, a plate PT, an adhesive film AF, a display panel DP, a polymer layer POL, a window layer WL, an adhesive layer ADL, and a protective film PL.

The cover film CF may be disposed on a rear surface of the display device DD. The cover film CF may be used to protect the display device DD from impact and to alleviate external strain applied thereto. The cover film CF may include a sponge, a foam, a thermoplastic polyurethane, and/or polydimethylacrylamide. They may be used alone or in combination with each other. Optionally, the cover film CF may include a light blocking material. Accordingly, the cover film CF may absorb light incident from a rear surface of the display device DD.

The plate PT may be disposed on the cover film CF. The plate PT may prevent the display panel DP from being bent by external force. For example, the plate PT may maintain the display panel DP in a relatively flat state even when an external force is applied from outside the display device DD. The plate PT may include a rigid or semi-rigid material. For example, the plate PT may include iron, chromium, carbon, nickel, silicon, manganese, and/or molybdenum. These may be used alone or in combination with each other. However, embodiments of the present disclosure are not necessarily limited thereto.

The adhesive film AF may be disposed on the plate PT. The adhesive film AF may attach the plate PT and the display panel DP to one another. For example, the adhesive film AF may include a pressure sensitive adhesive (PSA), an optical clear adhesive (OCA), and/or an optical clear resin (OCR). However, embodiments of the present disclosure are not necessarily limited thereto.

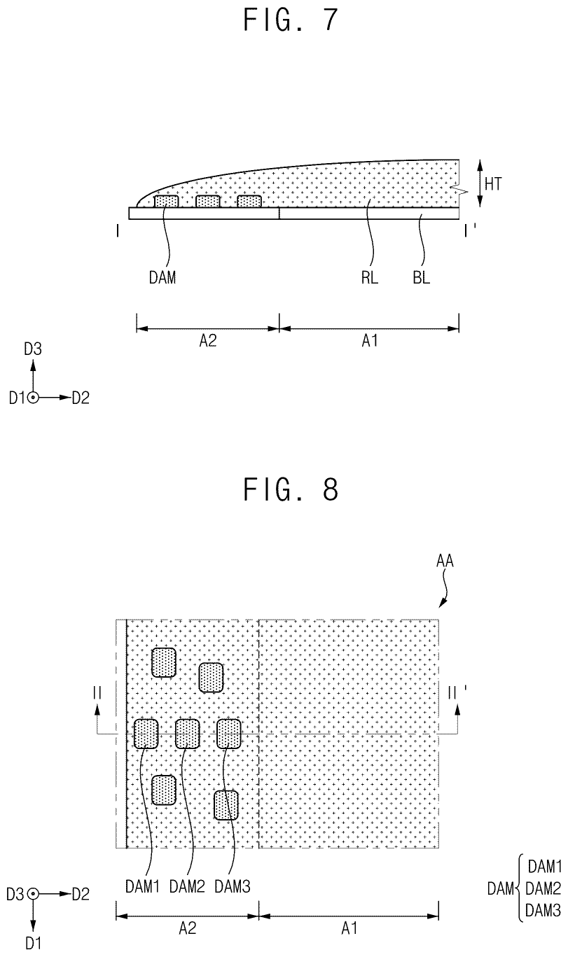

The display panel DP may be disposed on the adhesive film AF. The display panel DP may generate light based on a provided signal. Accordingly, the display panel DP may provide a visual image to the user of the display device DD. The display panel DP will be described in detail later with reference to FIG. 7.

The polymer layer POL may be disposed on the display panel DP. The polymer layer POL may attach the display panel DP and the window layer WL to one another. In addition, the polymer layer POL may support the window layer WL from sagging and protect the display panel DP from external shocks, etc. The polymer layer POL may have a single-layer or a multi-layer structure.

The window layer WL may be disposed on the polymer layer POL. The window layer WL may cover a front surface of the display device DD and protect the display panel DP. The window layer WL may include a substantially transparent material. For example, the window layer WL may be glass or plastic. However, embodiments of the present disclosure are not necessarily limited thereto.

The adhesive layer ADL may be disposed on the window layer WL. The adhesive layer ADL may attach the window layer WL and the protective film PL to one another. The adhesive layer ADL may include a transparent material. For example, the adhesive layer ADL may include a pressure sensitive adhesive (PSA), an optical clear adhesive (OCA), and/or an optical clear resin (OCR). However, embodiments of the present disclosure are not necessarily limited thereto.

The protective film PL may be disposed on the adhesive layer ADL. The protective film PL may protect the window layer WL from external impacts and/or scratches. For example, the protective film PL may include a base layer and a hard coating layer. However, embodiments of the present disclosure are not necessarily limited thereto. The protective film PL may further include a low refractive index layer and/or an anti-fingerprint layer.

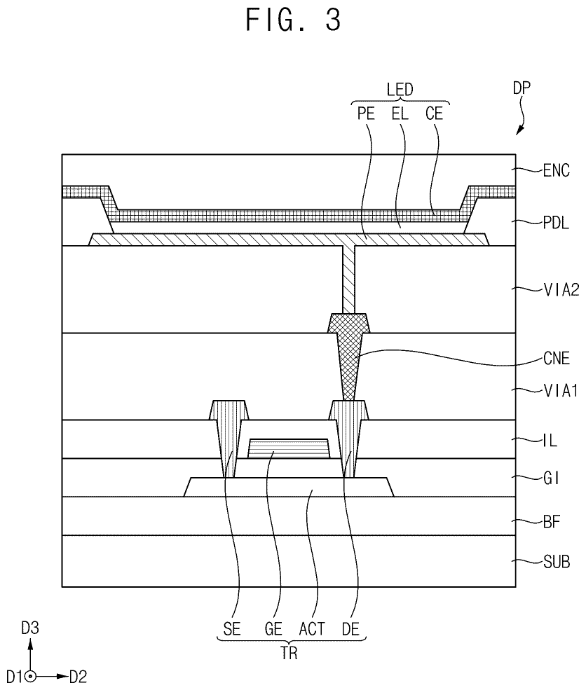

FIG. 3 is a cross-sectional view showing a cross-section of the display panel of FIG. 2.

Referring to FIGS. 1, 2, and 3, the display panel DP may include the substrate SUB, a buffer layer BF, a gate insulating layer GI, a transistor TR, an interlayer insulating layer IL, a connection electrode CNE, a first via layer VIA1, a second via layer VIA2, a light emitting diode LED, a pixel defining layer PDL, and an encapsulation layer ENC.

The transistor TR may include an active layer ACT, a gate electrode GE, a source electrode SE, and a drain electrode DE. The light emitting diode LED may include a pixel electrode PE, a light emitting layer EL, and a common electrode CE.

The substrate SUB may include a glass substrate, a metal substrate, a plastic substrate, etc. However, embodiments of the present disclosure are not necessarily limited thereto, and the substrate SUB may be an inorganic layer, an organic layer, or a composite material layer.

The buffer layer BF may be disposed on the substrate SUB. The buffer layer BF may prevent impurities such as oxygen and moisture from penetrating into an upper part of the substrate SUB. The buffer layer BF may include an inorganic insulating material.

The active layer ACT may be disposed on the buffer layer BF. The active layer ACT may include an oxide semiconductor, a silicon semiconductor, an organic semiconductor, etc. For example, the oxide semiconductor may include indium (In), gallium (Ga), tin (Sn), zirconium (Zr), vanadium (V), hafnium (Hf), cadmium (Cd), germanium (GE), chromium (Cr), titanium (Ti), and/or zinc (Zn). The silicon semiconductor may include amorphous silicon, polycrystalline silicon, etc. The active layer ACT may include a source region, a drain region, and a channel region disposed between the source region and the drain region.

The gate insulating layer GI may be disposed on the buffer layer BF. For example, the gate insulating layer GI may cover the active layer ACT on the buffer layer BF. The gate insulating layer GI may include an inorganic insulating material. In an embodiment, the gate insulating layer GI may be formed entirely in the display area DA and the peripheral area SA.

The gate electrode GE may be disposed on the gate insulating layer GI. The gate electrode GE may at least partially overlap the channel region of the active layer ACT. The gate electrode GE may include an electrically conductive material such as a metal, alloy, conductive metal nitride, conductive metal oxide, or transparent conductive material. Examples of the electrically conductive material that may be used in the gate electrode GE may include gold (Au), silver (Ag), aluminum (Al), platinum (PT), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloy containing aluminum, alloy containing silver, alloy containing copper, alloy containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), etc. These may be used alone or in combination with each other. Optionally, the gate electrode GE may have a single-layer structure or a multi-layer structure including a plurality of electrically conductive layers.

The interlayer insulating layer IL may be disposed on the gate electrode GE. For example, the interlayer insulating layer IL may be disposed on the gate insulating layer GI and cover the gate electrode GE on the gate insulating layer GI. The interlayer insulating layer IL may include an inorganic insulating material.

The source electrode SE and the drain electrode DE may be disposed on the interlayer insulating layer IL. Each of the source electrode SE and the drain electrode DE may be connected to the active layer ACT. For example, the source electrode SE may contact the source region of the active layer ACT, and the drain electrode DE may contact the drain region of the active layer ACT. Each of the source electrode SE and the drain electrode DE may include an electrically conductive material. The active layer ACT, the gate electrode GE, the source electrode SE, and the drain electrode DE may form the transistor TR.

The first via layer VIA1 may be disposed on the source electrode SE and the drain electrode DE. For example, the first via layer VIA1 may be disposed on the interlayer insulating layer IL and may cover the source electrode SE and the drain electrode DE on the interlayer insulating layer IL. The first via layer VIA1 may include an organic insulating material. In an embodiment, the first via layer VIA1 may be formed exclusively in the display area DA and a portion of the peripheral area SA adjacent to the display area DA.

The connection electrode CNE may be disposed on the first via layer VIA1. The connection electrode CNE may transmit a signal transmitted from the transistor TR to the light emitting diode LED. The connection electrode CNE may include metal, alloy, metal nitride, conductive metal oxide, transparent conductive material, etc. These may be used alone or in combination with each other. However, embodiments of the present disclosure are not necessarily limited thereto.

The second via layer VIA2 may be disposed on the connection electrode CNE. For example, the second via layer VIA2 may be disposed on the first via layer VIA1 and cover the connection electrode CNE. The second via layer VIA2 may include substantially a same material as the first via layer VIA1.

The pixel electrode PE may be disposed on the second via layer VIA2. The pixel electrode PE may include an electrically conductive material. The pixel electrode PE may be connected to the drain electrode DE through the connection electrode CNE. Accordingly, the pixel electrode PE may be electrically connected to the transistor TR.

The pixel defining layer PDL may be disposed on the pixel electrode PE. For example, the pixel defining layer PDL may expose at least a portion of the pixel electrode PE. The pixel defining layer PDL may include an inorganic insulating material or an organic insulating material.

The light emitting layer EL may be disposed on the pixel electrode PE. For example, the light emitting layer EL may be disposed within an opening defined by the pixel defining layer PDL. For example, the light emitting layer EL may be surrounded by the pixel defining layer PDL. The light emitting layer EL may include an organic light emitting material and/or quantum dots. However, embodiments of the present disclosure are not necessarily limited thereto.

The common electrode CE may be disposed on the light emitting layer EL. The common electrode CE may also be disposed on the pixel defining layer PDL. For example, the common electrode CE may be continuously disposed on the light emitting layer EL and the pixel defining layer PDL. The common electrode CE may include an electrically conductive material. The light emitting layer EL may emit light based on a voltage difference between the pixel electrode PE and the common electrode CE.

The encapsulation layer ENC may be disposed on the common electrode CE. The encapsulation layer ENC may include at least one inorganic encapsulation layer and at least one organic encapsulation layer. In an embodiment, the inorganic encapsulation layer and the organic encapsulation layer may be alternately disposed. For example, the organic encapsulation layer may include a cured polymer such as polyacrylate, epoxy resin, or silicone resin. For example, the inorganic encapsulation layer may include silicon oxide, silicon nitride, silicon carbide, aluminum oxide, tantalum oxide, hafnium oxide, zirconium oxide, titanium oxide, etc.

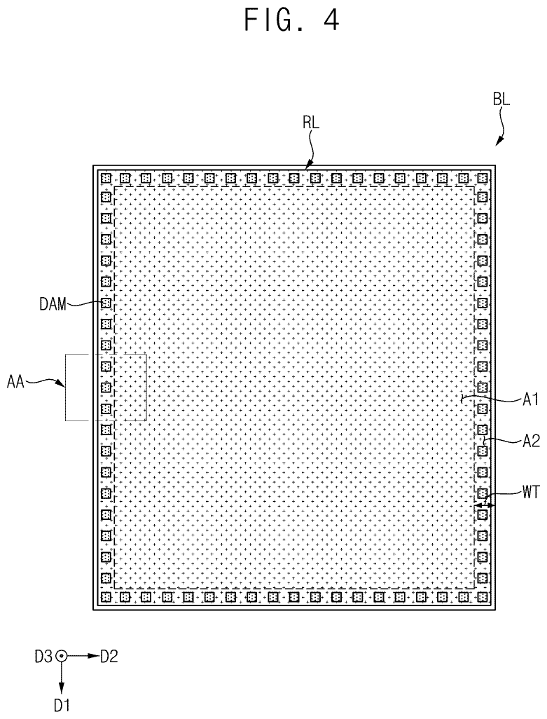

FIG. 4 is a plan view showing an embodiment of a base layer included of FIG. 2. For example, a base layer BL may be any one of components constituting the display device DD shown in FIG. 2. For example, the base layer BL may be the display panel DP including the light emitting diode LED that emits light. However, embodiments of the present disclosure are not necessarily limited thereto.

Referring to FIGS. 2 and 4, dams DAM may be disposed on the base layer BL, and a resin layer RL may cover the base layer BL and upper surfaces of the dams DAM.

The base layer BL may include a first area A1 and a second area A2 proximate to, for example, surrounding the first area A1. The second area A2 may have a width within a certain range and may surround the first area A1. For example, a width WT of the second area A2 may be about 5 mm or less. For example, the width WT of the second area may be about 3 mm or less.

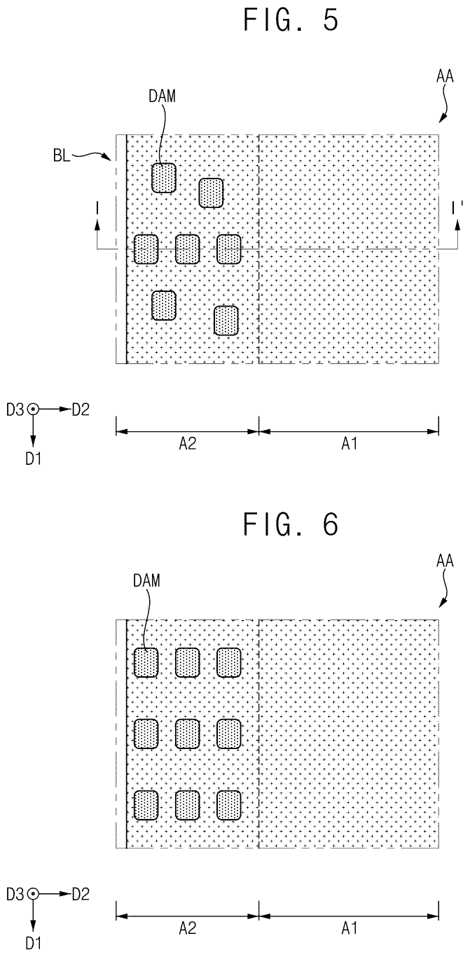

The second area A2 may be an area where the dams DAM are disposed. For example, the dams DAM may be disposed on an upper surface of the second area A2 and may be disposed surrounding the first area A1 of the base layer BL. As shown in FIG. 4, a plurality of dams DAM may be disposed in the second area A2. An arrangement of the dams DAM will be described later with reference to FIGS. 5, 6, 7, 8, and 9.

The dams DAM may include resin. For example, the dams DAM may include a urethane resin, an acrylic resin, and/or an epoxy resin. These may be used alone or in combination with each other. However, embodiments of the present disclosure are not necessarily limited thereto.

In an embodiment, the upper surface of the base layer BL on which the dams DAM are disposed may have hydrophilic properties. Since the upper surface of the base layer BL has hydrophilicity (i.e. is hydrophilic), the dams DAM having hydrophilicity may be stably disposed on the upper surface of the base layer BL.

The resin layer RL may be disposed on the base layer BL. For example, the resin layer RL may be disposed on the base layer BL and may cover upper surfaces of the dams DAM. By covering the dams DAM with the resin layer RL, shrinkage of the resin layer RL in a direction of the first area A1 may be prevented or reduced. For example, when the resin layer RL is cured on the base layer BL, the resin layer RL may shrink in a direction of the first area A1. However, as resistance to shrinkage is generated by the dams DAM disposed in the second area A2, shrinkage of the resin layer RL in a direction of the first area A1 may be prevented or reduced. Thus, the dams may act as anchors to prevent the resin layer RL from pulling away.

In an embodiment, a planar area of the resin layer RL may be about 95% or more of a planar area of the base layer BL. For example, a planar area of the resin layer RL may be about 97% or more of a planar area of the base layer BL. When a planar area of the resin layer RL satisfies a range described above, the base layer BL and other components of the display device DD disposed on the base layer BL may be stably attached.

The resin layer RL may include a same material as the dams DAM. For example, the resin layer RL may include a urethane resin, an acrylic resin, and/or an epoxy resin. These may be used alone or in combination with each other. However, embodiments of the present disclosure are not necessarily limited thereto. Since the dams DAM and the resin layer RL include a same material, chemical reactions that may otherwise occur at an interface where the dams DAM meet the resin layer RL may be prevented or reduced.

In an embodiment, a sum of the planar areas of each of the dams DAM may be about 50% or more of a planar area of the second area A2. For example, a sum of the planar areas of each of the dams DAM may be about 60% or more of a planar area of the second area A2. By disposing the dams DAM on an upper surface of the second area A2 within a range described above, the dams DAM may effectively prevent shrinkage of the resin layer RL.

FIG. 5 is an enlarged plan view of an embodiment of AA of FIG. 4. FIG. 6 is an enlarged plan view of an embodiment of AA of FIG. 4.

Referring to FIGS. 4, 5, and 6, a plurality of dams DAM may be disposed in the second area A2 of the base layer BL. The dams DAM may be spaced apart from one another in the first direction D1 and/or the second direction D2. The dams DAM may be spaced apart from one another diagonally.

For example, the dams DAM may be randomly disposed (e.g., without obvious order) as shown in FIG. 5. For example, one of the dams DAM may be spaced apart from the other one of the dams DAM in a diagonal direction and may be disposed side by side in the first direction D1 and/or the second direction D2.

For another example, each of the dams DAM may be disposed side by side in the first direction D1 and side by side in the second direction D2 on the base layer regularly as shown in FIG. 6. At this time, a separation distance between each of the dams DAM may be the same. However, embodiments of the present disclosure are not necessarily limited thereto. Even when the dams DAM are disposed side by side in the first direction D1 and/or the second direction D2, a separation distance between the dams DAM may be different.

A planar shape of each of the dams DAM may be polygonal. For example, a planar shape of each of the dams DAM may be that of a triangle, a square, and/or a straight line. However, embodiments of the present disclosure are not necessarily limited thereto.

FIG. 7 is a cross-sectional view taken along line I-I′ of FIG. 5.

Referring to FIGS. 5 and 7, the dams DAM may be disposed in the second area A2 of the base layer BL, and the resin layer RL may cover an upper surface of each of the dams DAM. For example, a thickness HT of the resin layer RL in any of the first area A1 and the second area A2 may be greater than a height of each of the dams DAM.

For example, the thickness HT of the resin layer RL may be about 100 μm or less. Since the thickness HT in any one of the first area A1 and the second area A2 of the resin layer RL covering upper surfaces of the dams DAM may be greater than a height of each of the dams DAM, a height of each of the dams DAM may be about 100 μm or less. For example, a height of each of the dams DAM may be about 80 μm or less.

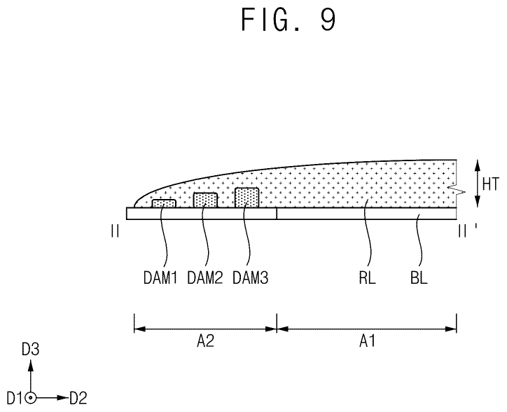

In an embodiment, each of the dams DAM may have a same height. For example, as shown in FIG. 7, each of the dams DAM may have a same height. The dams DAM having different heights will be described later with reference to FIGS. 8 and 9.

In FIG. 7, the dams DAM are described as being disposed on an upper surface of the base layer BL, but the embodiment of the present disclosure is not necessarily limited thereto. The dams DAM may also be disposed on a lower surface of the base layer BL. For example, when the base layer BL is the display panel (e.g., the display panel DP of FIG. 2), the dams DAM may be disposed on an upper surface and lower surface of the display panel (e.g., the display panel DP of FIG. 2).

FIG. 8 is an enlarged plan view of an embodiment of AA of FIG. 4. FIG. 9 is a cross-sectional view taken along line II-II′ of FIG. 8. A description referring to FIGS. 8 and 9 may differ from the description referring to FIGS. 5 and 7 in a height of each of the dams DAM. Therefore, to the extent that an element is not described in detail with respect to this figure, it may be understood that the element is at least similar to a corresponding element that has been described elsewhere within the present disclosure.

Referring to FIGS. 8 and 9, the dams DAM may include a first dam DAM1, a second dam DAM2, and a third dam DAM3.

In this specification, the first dam DAM1, the second dam DAM2, and the third dam DAM3 are terms introduced to distinguish three randomly selected dams among the dams DAM. For example, in this specification, the three randomly selected dams among the dams DAM are distinguished based on their proximity to the first area A1. For example, the third dam DAM3 may be a term referring to the dam closest to the first area A1 among the three randomly selected dams, and the first dam DAM1 may be a term referring to the dams furthest from the first area A1 among the dams, and the second dam DAM2 may be a term referring to one dam other than the first dam DAM1 and the third dam DAM3.

Hereinafter, an embodiment of the present disclosure will be focused on the first dam DAM1, the second dam DAM2, and the third dam DAM3 randomly selected among the dams DAM shown in FIG. 8.

In FIG. 8, the first dam DAM1, the second dam DAM2, and the third dam DAM3 are shown as being disposed side by side in the second direction D2, but the embodiment of the present disclosure are not necessarily limited thereto. Each of the first dam DAM1, the second dam DAM2, and the third dam DAM3 may be spaced apart from one another in the first direction D1 and/or the second direction D2. For example, each of the first dam DAM1, the second dam DAM2, and the third dam DAM3 may be diagonally spaced apart from each other. For example, if the second dam DAM2 is disposed closer to the first area A1 of the base layer BL than the first dam DAM1, and the third dam DAM3 is disposed closer to the first area A1 of the base layer BL than the second dam DAM2, it may correspond to the embodiment of the present invention.

The first dam DAM1 may have a first height, the second dam DAM2 may have a second height, and the third dam DAM3 may have a third height. The first height, the second height, and the third height may be different from each other. For example, each of the first height, the second height, and the third height may be different from each other. However, embodiments of the present disclosure are not necessarily limited thereto. For another example, the first height may be different from the second height, and the second height may be same as the third height.

In an embodiment, the second height may be greater than the first height, and the third height may be greater than the second height. For example, a height of another dam disposed closer to the first area A1 among the dams DAM may be greater than or same to a height of any one of the dams DAM. For example, as shown in FIG. 9, the third height of the third dam DAM3 may be greater than the second height of the second dam DAM2, and the second height of the second dam DAM2 may be greater than the first height of the first dam DAM1.

The thickness HT of the resin layer RL may increase as it approaches a center of the first area A1. Accordingly, as a dam among the dams DAM disposed relatively closer to the first area A1 has a higher height, so that shrinkage of the resin layer RL in a direction of the first area A1 may be effectively prevented or reduced.

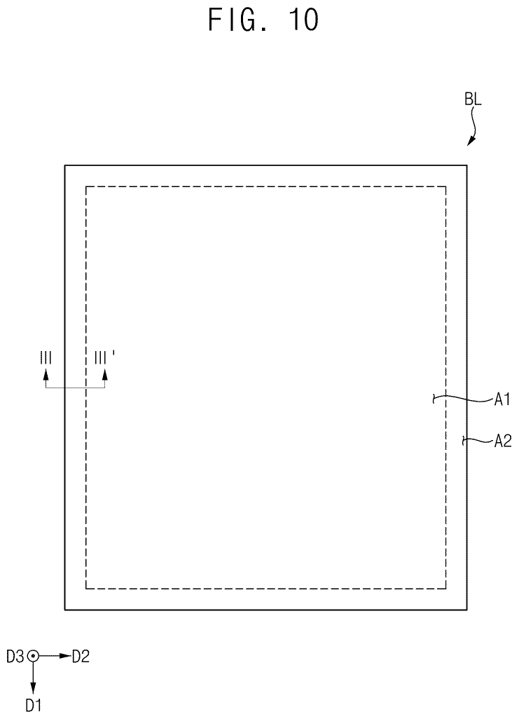

FIGS. 10, 11, 12, 13, 14, 15, 16, and 17 are views showing a method of manufacturing the dams and the resin layer of FIG. 9.

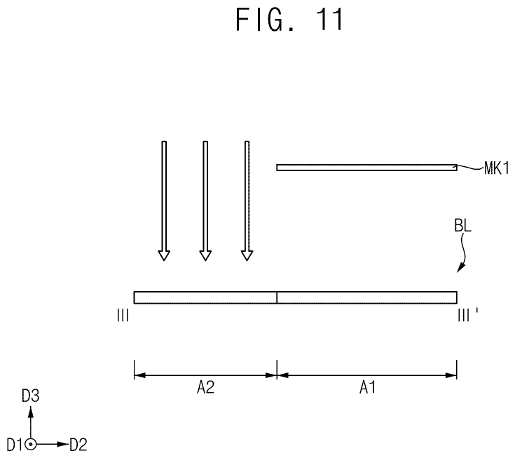

Referring to FIGS. 10 and 11, a first mask MK1 may be disposed on the first area A1 of the base layer BL, and a first surface treatment process may be performed exclusively on an upper surface of the second area A2. The first surface treatment process may be a hydrophilic treatment process. For example, by performing the first surface treatment process exclusively on an upper surface of the second area A2 of the base layer BL, an upper surface of the second area A2 may be relatively more hydrophilic than an upper surface of the first area A1. The first surface treatment process may be a treatment process using plasma.

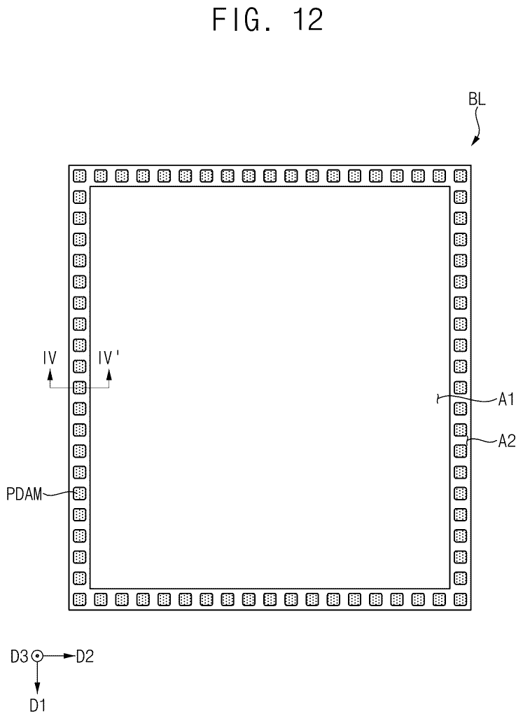

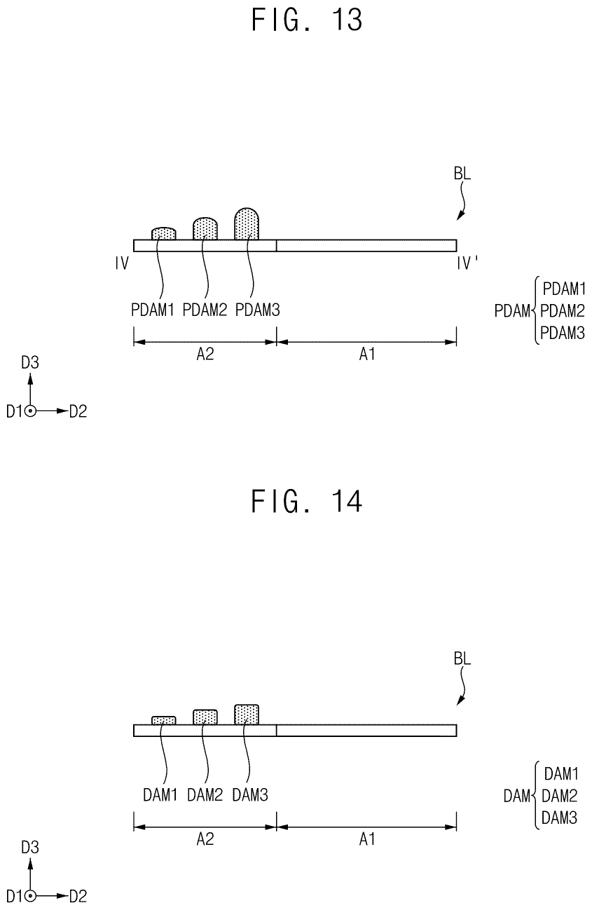

Referring further to FIGS. 12 and 13, dam resins PDAM may be applied to an upper surface of the second area A2 on which the first surface treatment process has been completed. When the dam resins PDAM are cured, the dams (e.g., the dams DAM of FIG. 14) may be formed. For example, the dam resins PDAM may be preliminary components of the dams (e.g., the dams DAM of FIG. 14) including a same material as the dams (e.g., the dams DAM of FIG. 14).

The dam resins PDAM may include a first dam resin PDAM1, a second dam resin PDAM2, and a third dam resin PDAM3. The second dam resin PDAM2 may be formed closer to the first area A1 than the first dam resin PDAM1, and the third dam resin PDAM3 may be formed closer to the first area A1 than the second dam resin PDAM2.

In an embodiment, each of the dam resins PDAM may have different heights. For example, a height of the second dam resin PDAM2 may be greater than the height of the first dam resin PDAM1. A height of the third dam resin PDAM3 may be greater than the height of the second dam resin PDAM2. However, embodiments of the present disclosure are not necessarily limited thereto. Some of the dam resins PDAM may have the same height, and other portions may have different heights.

In an embodiment, a contact angle formed by each of the dam resins PDAM with an upper surface of the base layer BL may be about 90 degrees or less. For example, the contact angle formed by each of the dam resins PDAM and an upper surface of the base layer BL may be about 80 degrees or less. As an upper surface of the second area A2 of the base layer BL has hydrophilicity through the first surface treatment process, each of an upper surface of the base layer BL and the dam resins PDAM may be formed stably while having the contact angle.

In an embodiment, the dam resins PDAM may be formed through an inkjet printing method. However, embodiments of the present disclosure are not necessarily limited thereto. The dam resins PDAM may be formed on the second area A2 through an electrohydrodynamic (EHD) printing process, nano implant process, dispenser process, etc.

Referring further to FIG. 14, the dam resins PDAM may be cured. As the dam resins PDAM is cured, the first dam DAM1, the second dam DAM2, and the third dam DAM3 may be formed. For example, the first dam resin PDAM1 may be cured to form the first dam DAM1, the second dam resin PDAM2 may be cured to form the second dam DAM2, and the third dam PDAM3 may be cured to form the third dam DAM3. In FIG. 13, since heights of the first dam resin PDAM1, the second dam resin PDAM2, and the third dam resin PDAM3 were different, heights of each of the first dam DAM1, the second dam DAM2, and the third dam DAM3 may also be different. However, as shown in FIG. 7, each of the dams DAM may have the same height.

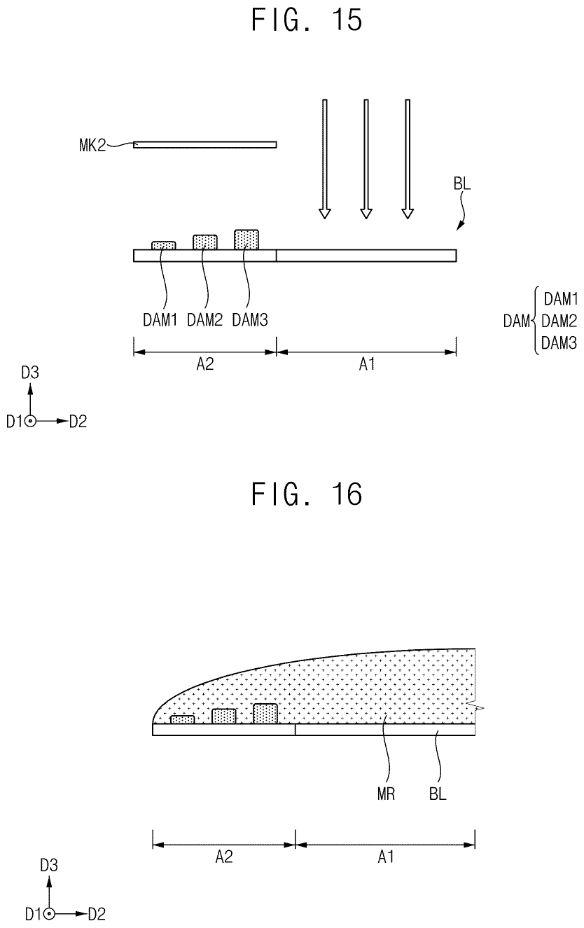

Referring further to FIG. 15, a second mask MK2 may be disposed on the second area A2 of the base layer BL, and a second surface treatment process may be performed exclusively on an upper surface of the first area A1. The second surface treatment process may be substantially same as the first surface treatment process. For example, the second surface treatment process may be a surface treatment process that uses plasma to make an upper surface of the first area A1 hydrophilic.

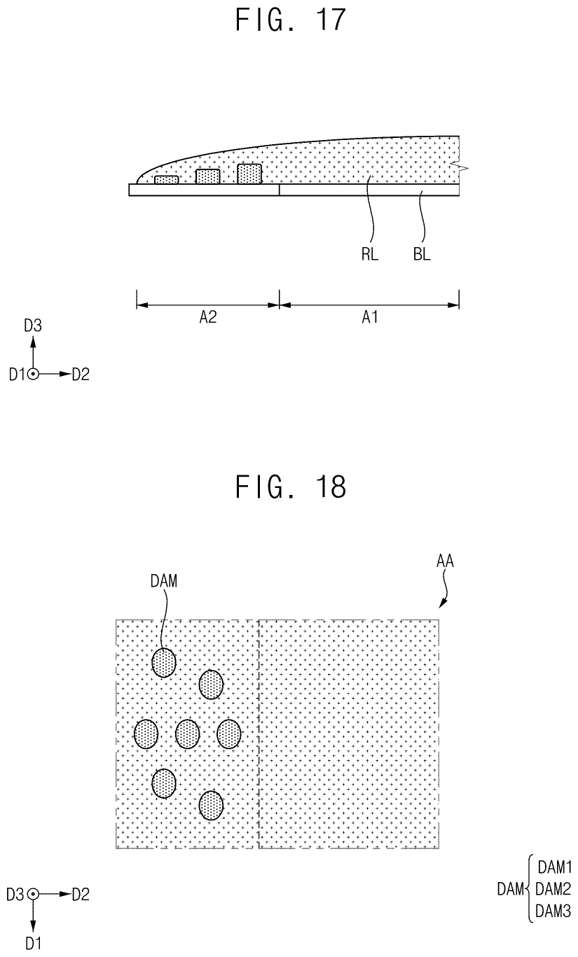

For example, after the second surface treatment process, surface characteristics of each of an upper surface of the first area A1 and an upper surface of the second area A2 of the base layer BL may be substantially same. For example, by performing the second surface treatment process on the first area A1 of the base layer BL and performing the first surface treatment process on the second area A2 of the base layer BL, both an upper surface of the first area A1 and an upper surface of the second area A2 may have hydrophilicity. As both an upper surface of the first area A1 and the upper surface of the second area A2 have hydrophilic properties, so that the resin layer (e.g., the resin layer RL in FIG. 17) may be stably formed on an upper surface of base layer BL.

Referring further to FIGS. 16 and 17, the main resin MR may be applied to the first area A1 and the second area A2 of the base layer BL. The main resin MR may include a same material as the dam resins PDAM. For example, the main resin MR may include a urethane resin, an acrylic resin, and an epoxy resin. These may be used alone or in combination with each other. However, embodiments of the present disclosure are not necessarily limited thereto.

In an embodiment, after performing the second surface treatment process, a contact angle formed by the main resin MR with each of an upper surface of the first area A1 and an upper surface of the second area A2 may be substantially same. For example, an upper surface of the first area A1 and an upper surface of the second area A2 have hydrophilicity through substantially a same process, so that an upper surface of the first area A1 and an upper surface of the second area A2 may have substantially same surface characteristics.

Thereafter, the main resin MR may be cured to form the resin layer RL as shown in FIG. 17. As the main resin MR cured, the main resin MR may shrink in a direction of the first area A1. For example, the resin layer RL may be formed to be partially shrunken in a direction of the first area A1.

However, since the dams DAM are formed in the second area A2, when the main resin MR shrinks, resistance to a shrinkage of the main resin MR in a direction of the first area A1 may occur. Accordingly, shrinkage of the main resin MR may be prevented or reduced. As a result, a planar area of the resin layer RL resisted by the dams DAM may increase compared to any resin layer formed in an absence of the dams DAM. Accordingly, when the polymer layer (e.g., polymer layer POL in FIG. 2) is attached to the base layer BL, the polymer layer POL may be stably attached. In addition, an external display quality of the display device (e.g., the display device DD of FIG. 1) may be increased.

FIG. 18 is an enlarged plan view of an embodiment of AA of FIG. 4. For example, since the description referring to FIG. 18 is same as a description referring to FIG. 5 except for the planar shape of the dams DAM, to the extent that an element is not described in detail with respect to this figure, it may be understood that the element is at least similar to a corresponding element that has been described elsewhere within the present disclosure.

Referring to FIG. 18, the dams DAM may be disposed in the second area A2 of the base layer BL. The dams DAM may be disposed randomly (e.g., without an observable pattern) or regularly.

In an embodiment, a planar shape of each of the dams DAM may be circular as shown in FIG. 18. However, embodiments of the present disclosure are not necessarily limited thereto. A planar shape of each of the dams DAM may include various shapes, such as an oval shape or a rectangle shape.

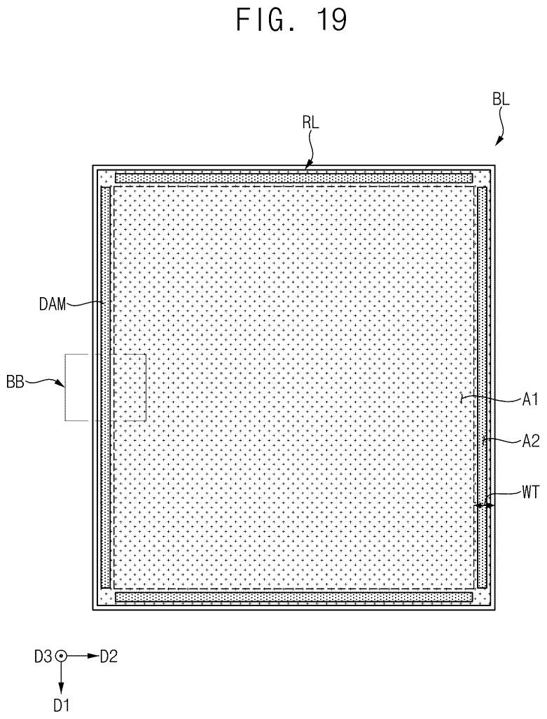

FIG. 19 is a plan view showing an embodiment of the base layer included in FIG. 2. For example, a description referring to FIG. 19 may be substantially same except for the dams DAM in FIG. 4. Therefore, to the extent that an element is not described in detail with respect to this figure, it may be understood that the element is at least similar to a corresponding element that has been described elsewhere within the present disclosure.

Referring to FIG. 19, each of the dams DAM may extend primarily in one direction in the second area A2 of the base layer BL. For example, two of the dams DAM that are spaced apart in the second direction D2 across the first area A1 may extend in the first direction D1. For example, two of the dams DAM that are spaced apart in the first direction D1, across the second area A2, may extend in the second direction D2. For example, unlike the dams DAM shown in FIG. 4, each of the dams DAM shown in FIG. 19 may extend in the first direction D1 or the second direction D2 on one side of the second area A2.

However, embodiments of the present disclosure are not necessarily limited thereto. In FIG. 19, each of the dams DAM is shown as being disconnected at a corner, but each of the dams DAM may be connected at a corner of the second area A2. For example, each of the dams DAM may be formed integrally without being separated from each other.

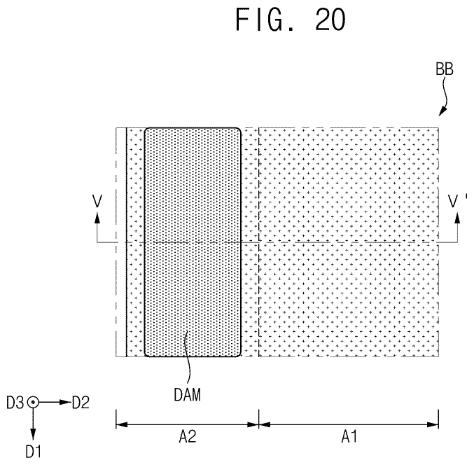

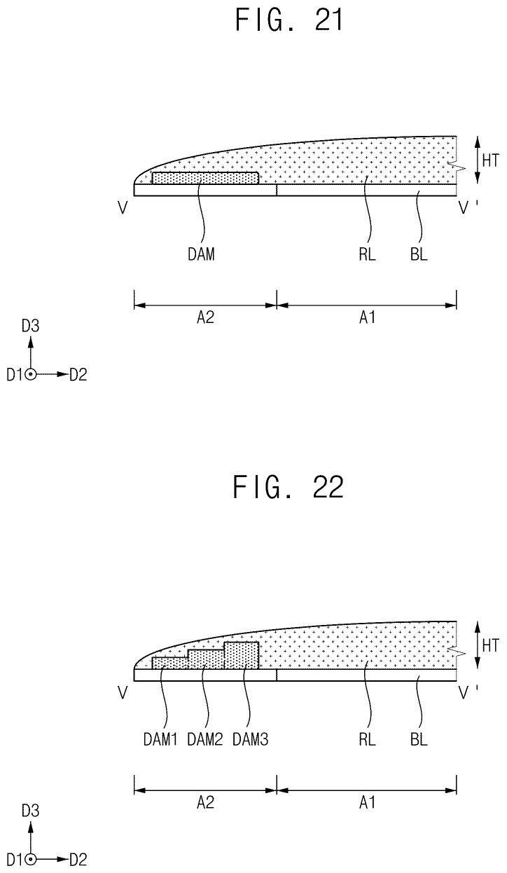

FIG. 20 is an enlarged plan view of BB of FIG. 19. FIG. 21 is a cross-sectional view of an embodiment taken along line V-V′ of FIG. 20. FIG. 22 is a cross-sectional view of an embodiment taken along line V-V′ of FIG. 20.

For example, a description referring to FIG. 20 may be same as a description referring to FIG. 8 except for a planar shape of the dams DAM. In addition, a description referring to FIGS. 21 and 22 may be same as a description referring to FIG. 9 except for a cross-sectional shape of the dams DAM. Therefore, to the extent that an element is not described in detail with respect to this figure, it may be understood that the element is at least similar to a corresponding element that has been described elsewhere within the present disclosure.

Referring to FIGS. 20 and 21, one of the dams DAM may be disposed in the second area A2 of the base layer BL, extending in the first direction D1. Upper surfaces of the dams DAM may be flat. For example, a level of an upper surface of the dams DAM on an upper surface of the base layer BL may be same regardless of a position in the second direction D2.

Referring further to FIG. 22, a cross-sectional shape of the dams DAM may have a shape that increases in a direction approaching the first area A1. For example, one of the dams DAM may have the first dam DAM1, the second dam DAM2, and the third dam DAM3. As shown in FIG. 22, the first dam DAM1, the second dam DAM2, and the third dam DAM3 may be disposed adjacent to each other. For example, the first dam DAM1, the second dam DAM2, and the third dam DAM3 may be formed integrally. By increasing a height of the dams DAM in a direction closer to the first area A1, shrinkage that occurs when the resin layer RL is formed may be effectively prevented or reduced.

The structures and techniques described within the present disclosure may be applied to the display device and the electronic device including a same. For example, the present disclosure may be applied to high-resolution display smartphones, mobile phones, smart pads, smart watches, tablet computers, vehicle navigation systems, televisions, computer monitors, laptops, etc.

While the disclosure has been particularly shown and described with reference to embodiments thereof, it will be understood by those of ordinary skill in the art that various changes in form and details may be made therein without departing from the spirit or scope of the disclosure.

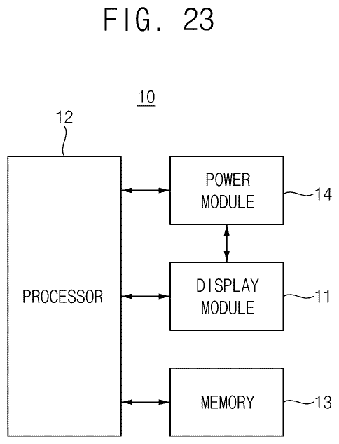

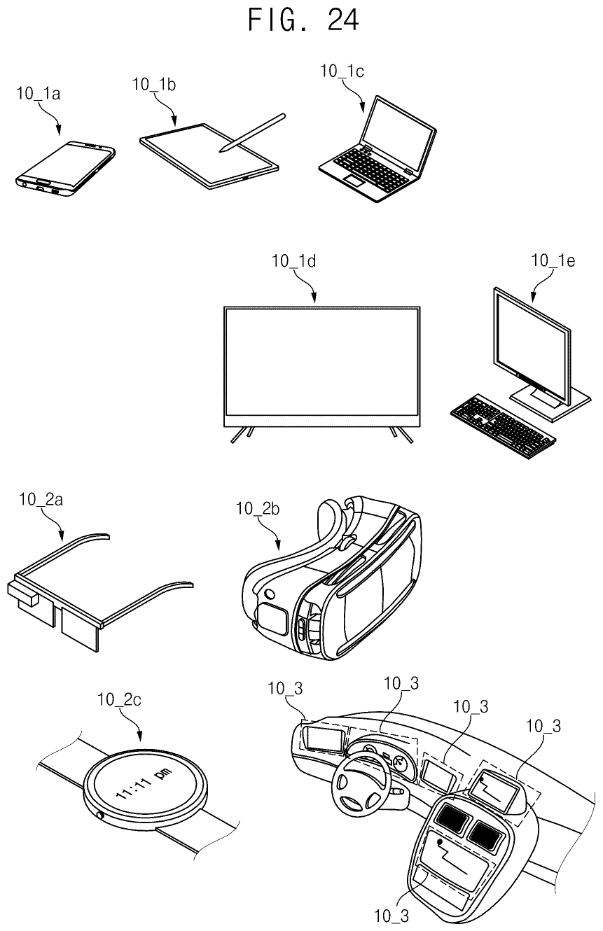

FIG. 23 is a block-diagram showing an electronic device according to an embodiment of the present disclosure.

Referring to FIGS. 1 and 23, the display device DD according to the embodiments may be applied to various electronic devices 10. The electronic device 10 according to an embodiment may include the display device DD, and may further include a module or device having additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module such as a power adapter or a battery device, and a power conversion module that converts the power supplied by the power supply module to generate power necessary for the operation of the electronic device 10.

At least one of the components of the electronic device 10 described above may be included in the display device DD according to the embodiments described above. In addition, some of the individual modules functionally included in one module may be included in the display device DD, and other parts may be provided separately from the display device DD. For example, the display device DD may include the display module 11, and the processor 12, the memory 13, and the power module 14 may be provided in a form of another device within the electronic device 10 other than the display device DD.

FIG. 24 is a schematic diagram of the electronic device according to various embodiments of FIG. 23.

Referring to FIGS. 23 and 24, various electronic devices 10 to which the display device DD according to the embodiments is applied may include not only image display electronic devices such as a smart phone 10_1a, a tablet PC 10_1b, a laptop 10_1c, a TV 10_1d, a desk monitor 10_1e, but also wearable electronic devices including display modules such as smart glasses 10_2a, a head-mounted display 10_2b, a smart watch 10_2c, etc. and vehicle electronic devices 10_3 including display modules such as a CID (Center Information Display) disclosure on a dashboard, center fascia, or dashboard of a car, and a room mirror display.

However, this is exemplary, and the electronic devices 10 according to the embodiments of the present disclosure are not necessarily limited thereto. For example, the electronic device 10 may be implemented as a mobile phone, a video phone, a smart pad, a smart watch, a tablet PC, a vehicle display, a computer monitor, a notebook computer, a head-mounted display device, etc. In addition, the electronic device 10 may be a television, a monitor, a notebook computer, or a tablet. In addition, the electronic device 10 may be an automobile.

However, this is exemplary, and the electronic device ED according to the embodiments of the present disclosure is not necessarily limited thereto. For example, the electronic device ED may be implemented as a mobile phone, a video phone, a smart pad, a smart watch, a tablet PC, a vehicle display, a computer monitor, a notebook computer, a head-mounted display device, etc. In addition, the electronic device ED may be a television, a monitor, a notebook computer, or a tablet. In addition, the electronic device ED may be a car.

What is claimed is:

1. A display device, comprising:
a base layer including a first area and a second area proximate to the first area;
a first dam disposed in the second area on the base layer;
a second dam disposed in the second area on the base layer, the second dam being spaced apart from the first dam, and including a same material as the first dam; and
a resin layer disposed on the base layer, including a same material as the first dam and the second dam, and covering upper surfaces of each of the first dam and the second dam.

2. The display device of claim 1, wherein the base layer includes a display panel including a light emitting diode.

3. The display device of claim 1, wherein the second dam is disposed closer to the first area of the base layer than is the first dam.

4. The display device of claim 3, wherein the first dam has a first height and the second dam has a second height, and
wherein the first height of the first dam is different than the second height of the second dam.

5. The display device of claim 4, wherein the second height is greater than the first height.

6. The display device of claim 4, wherein each of the first height of the first dam and the second height of the second dam is about 100 μm or less.

7. The display device of claim 1, wherein a planar shape of each of the first dam and the second dam is a polygonal or circular shape.

8. The display device of claim 1, wherein an upper surface of the base layer on which the first dam and the second dam are disposed is hydrophilic.

9. The display device of claim 1, wherein each of the first dam and the second dam includes urethane resin, acrylic resin, and/or epoxy resin.

10. The display device of claim 1, wherein a planar area of the resin layer is about 95% or more of a planar area of the base layer.

11. The display device of claim 1, wherein a width of the second area is about 5 mm or less.

12. A method of manufacturing a display device, comprising:
performing a first surface treatment process on an upper surface of a second area of a base layer that includes a first area and the second area that is proximate to the first area;
applying dam resin to the second area on the base layer;
curing the dam resin to form a first dam and a second dam that is spaced apart from the first dam;
applying a main resin including a same material as that of the dam resin to the first area and the second area of the base layer; and
curing the main resin to form a resin layer covering upper surfaces of the first dam and the second dam.

13. The method of claim 12, wherein performing the first surface treatment process includes performing a hydrophilic treatment process on the upper surface of the second area of the base layer.

14. The method of claim 12, wherein in forming the first dam and the second dam, the second dam is formed closer to the first area of the base layer than is the first dam.

15. The method of claim 14, wherein the first dam has a first height and the second dam has a second height, and
wherein the second height of the second dam is different than the first height of the first dam.

16. The method of claim 15, wherein the second height of the second dam is greater than the first height of the first dam.

17. The method of claim 12, further comprising:
prior to applying the main resin, performing a second surface treatment process on an upper surface of the first area of the base layer.

18. The method of claim 17, wherein performing the second surface treatment process includes performing a hydrophilic treatment process on the upper surface of the first area of the base layer.

19. The method of claim 17, wherein each of the first surface treatment process and the second surface treatment process is a plasma treatment process.

20. The method of claim 12, wherein in applying dam resin,
the dam resin is applied through an inkjet printing method.

21. An electronic device comprising:
a display device; and
a processor configured to drive the display device, and
wherein the display device includes:
a base layer including a first area and a second area proximate to the first area;
a first dam disposed in the second area on the base layer;
a second dam disposed in the second area on the base layer, the second dam being spaced apart from the first dam, and including a same material as the first dam; and
a resin layer disposed on the base layer, including a same material as the first dam and the second dam, and covering upper surfaces of each of the first dam and the second dam.
